(19) United States
(12) Patent Application Publication
(10) Pub. No.: US 2022/0093650 A1
(43) Pub. Date: Mar. 24, 2022

(54) DISPLAY DEVICE

(71) Applicant: SHARP KABUSHIKI KAISHA, Sakai City, Osaka (JP)

(72) Inventors: TADAYOSHI MIYAMOTO, Sakai City, Osaka (JP); KAYO HARUGUCHI, Sakai City, Osaka (JP); YOSHINOBU NAKAMURA, Sakai City, Osaka (JP)

(21) Appl. No.: 17/413,486

(22) PCT Filed: Feb. 4, 2019
(86) PCT No.: PCT/JP2019/003902

§ 371 Date: Jun. 11, 2021

(51) Int. Cl. H01L 27/12

(52) U.S. Cl. CPC H01L 27/124; H01L 27/1225

(57) ABSTRACT

A display device includes a transistor including: a substrate; a lower electrode; a lower insulating film; an oxide semiconductor layer; a gate insulating film; and a gate electrode stacked on top of an other in a stated order. The gate electrode matches the gate insulating film in plan view. The oxide semiconductor layer includes: a channel region across the gate insulating film from the gate electrode; and a source region and a drain region provided to sandwich the channel region. The lower electrode extends to intersect with the oxide semiconductor layer in plan view. The lower electrode has: a source-side end face positioned toward the source region and overlap with the source region; and a drain-side end face positioned toward the drain region and overlap with the channel region.

### TECHNICAL FIELD

The present invention relates to a display device including a substrate on which a transistor is formed.

### BACKGROUND ART

Recent advancement in organic light-emitting diode (OLED) technologies allows increasing number of products to be provided with organic electroluminescence (EL) display devices. A typical organic EL display device includes a pixel circuit to supply a current to a pixel in a light-emitting layer. The pixel circuit is provided with a thin-film transistor. A known problem of the thin-film transistor is that, light entering a semiconductor layer generates an off-current, causing a deterioration in display performance. Hence, a technique is proposed to dispose a light-blocking film directly below the semiconductor layer to block the light (see, for example, Patent Document 1).

### CITATION LIST

### Patent Literature

[Patent Document 1] Japanese Unexamined Patent Application Publication No. 2015-170642

### SUMMARY OF INVENTION

### Technical Problem

In a display device disclosed in Patent Document 1, a thin-film transistor is provided on. an insulating substrate. The thin-film transistor includes a semiconductor layer provided with a channel region, a source region, and a drain region. Between the insulating substrate and the semiconductor layer, a light-blocking layer is provided. The light-blocking layer has an area overlapping the drain region more widely than the source region. In the above display device, the light-blocking layer, having a floating potential, does not influence an operation of the thin-film transistor. Hence, no consideration is given to adjustment for characteristics of the thin-film transistor.

The present invention is intended to overcome the above problem, and to provide a display device capable of maintaining a breakdown voltage high while maintaining an initial ON current of a transistor high.

### Solution to Problem

A display device according to the present invention includes: a transistor including: a substrate; a lower electrode; a lower insulating film; an oxide semiconductor layer; a gate insulating film; and a gate electrode stacked on top of an other in a stated order. The gate electrode matches the gate insulating film in plan view. The oxide semiconductor layer includes: a channel region across the gate insulating film from the gate electrode; and a source region and a drain region provided to sandwich the channel region. The lower electrode: extends to intersect with the oxide semiconductor layer in plan view, has a source-side end face positioned toward the source region, disposed in parallel with an end face of the channel region, and overlap with the source region, and has a drain-side end face positioned toward the drain region, disposed in parallel with an other end face of the channel region, and overlap with the channel region.

In the display device according to the present invention, when a direction in which the source region and the drain region face each other is defined as a channel length direction, the drain-side end face and an end face of the channel region may be spaced apart from each other at an off-set distance in the channel length direction.

In the display device according to the present invention, the off-set distance may be shorter than, or equal to, half as long as the channel region in the channel length direction.

The display device according to the present invention may further include a plurality of pixel circuits arranged in a matrix and provided to a display region. The transistor may be a switching transistor included in each of the pixel circuits.

The display device according to the present invention may further include a peripheral circuit monolithically provided to a frame region. The transistor may be a switching transistor included in the peripheral circuit.

The display device according to the present invention further may include: a terminal provided to a frame region; a routed wire extending from the terminal, and a filter circuit provided between the terminal and a display region. The terminal is electrically connected to a wire of the display region through the filter circuit. The transistor may be included in the filter circuit.

In the display device according to the present invention, the source region may be electrically connected to a high power-source voltage line. The drain region and the gate electrode may be electrically connected to the routed wire.

In the display device according to the present invention, the source region may be electrically connected to the routed wire. The drain region and the gate electrode may be electrically connected to a low power-source voltage line.

In the display device according to the present invention, the routed wire may be electrically connected to a data signal line of the display region.

In the display device according to the present invention, the routed wire may be electrically connected to a scanning signal line of the display region.

In the display device according to the present invention, the lower electrode may be electrically connected to the source region.

In the display device according to the present invention, the lower electrode may be electrically connected to a constant-potential voltage line.

### Advantageous Effects of Invention

In the present invention, a lower electrode is disposed closer toward a source region. Such a feature makes it possible to maintain a breakdown voltage high while maintaining an initial ON current high.

### BRIEF DESCRIPTION OF DRAWINGS

FIG. 1 is a cross-sectional view schematically illustrating a transistor of a display device according to a first embodiment of the present invention.

FIG. 2 is a plan view schematically illustrating the transistor in FIG. 1.

FIG. 3 is a block diagram schematically illustrating a display device according to a second embodiment of the present invention.

FIG. 4 is a circuit diagram illustrating a portion of a filter circuit using a transistor.

FIG. 5 is a plan view schematically illustrating some transistors of the filter circuit.

FIG. 6 is a cross-sectional view schematically viewed along arrows C-C in FIG. 5.

FIG. 7 is a cross-sectional view schematically viewed along arrows D-D in FIG. 5.

FIG. 8 is an equivalent circuit diagram illustrating a pixel circuit of the display device.

### DESCRIPTION OF EMBODIMENTS

### First Embodiment

Described below is a display device according to a first embodiment of the present invention, with reference to the drawings.

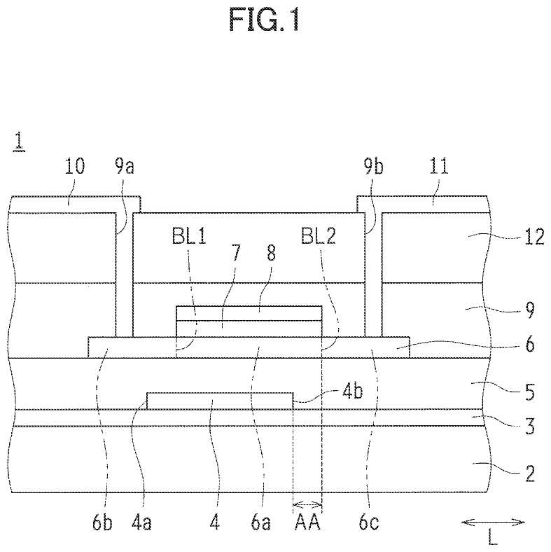

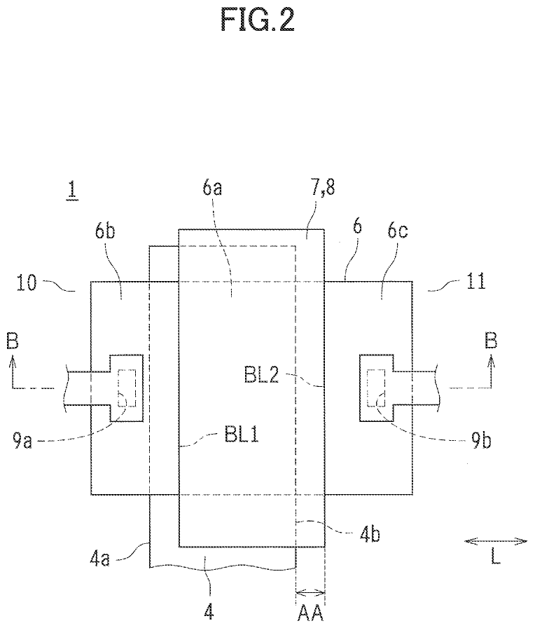

FIG. 1 is a cross-sectional view schematically illustrating a transistor of the display device according to the first embodiment of the present invention. FIG. 2 is a plan view schematically illustrating the transistor in FIG. 1. Note that, FIG. 1 is not hatched so that the drawing is easily viewable. In FIG. 2, a lower insulating film 5 and an interlayer insulating film are transparent. Moreover, FIG. 1 is equivalent to a cross-section taken along arrows B-B in FIG. 2.

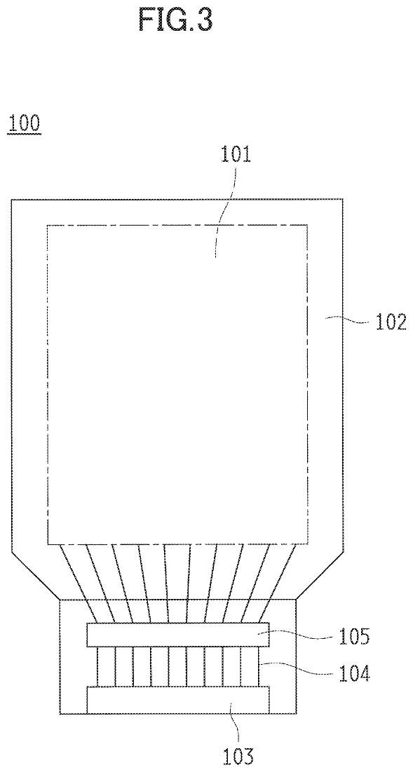

A display device 100 (see FIG. 3 later) according to the first embodiment of the present invention includes a transistor 1 (a thin-film transistor, or a TFT). The transistor 1 includes: a substrate 2; an underlayer 3; a lower electrode 4; a lower insulating film 5; an oxide semiconductor layer 6; a gate insulating film 7; a gate electrode 8; a first interlayer insulating film 9; a second interlayer insulating film 12; and a terminal electrode (a source electrode 10 and a drain electrode 11) stacked on top of an other in the stated order.

Illustrated in FIG. 1 is an enlarged view of one transistor 1 formed on the substrate 2. On the substrate 2, a plurality of the transistors may further be formed. The underlayer 3 is formed to cover the entire substrate 2. Node that, for the sake of description, a direction along the surface of the substrate 2 may be referred to as a channel length direction L.

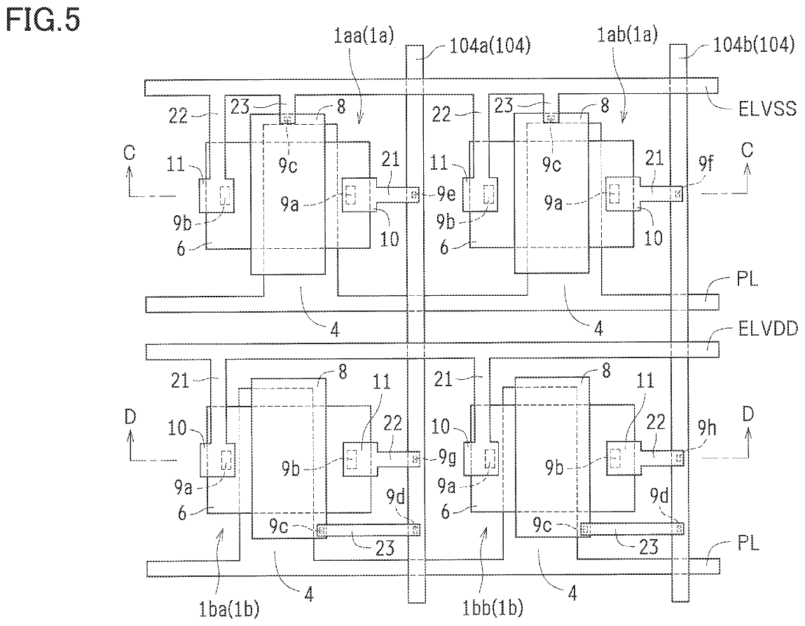

The lower electrode 4 is provided on the underlayer 3, and disposed for each transistor 1. Note that the lower electrode 4 may be provided to correspond to a channel region 6a of each of the transistors 1. As illustrated in FIG. 5 later, out of the channel region 6a, the lower electrode 4 may be connected to an other lower electrode 4 of a neighboring transistor 1 through a constant-potential voltage line PL. Moreover, a specific position of the lower electrode 4 will be described together with a position of the channel region 6a. The lower insulating film 5 is formed to cover the underlayer 3 and the lower electrode 4.

The oxide semiconductor layer 6 is provided on the lower insulating film 5, and disposed for each transistor 1. That is, the oxide semiconductor layer 6 is spaced apart from an oxide semiconductor layer 6 of an other transistor. The oxide semiconductor layer 6 includes: a conductive region (a source region 6b and a drain region 6c) positioned in either end of the oxide semiconductor layer 6 in the channel length direction L; and the channel region 6a positioned in a center of the oxide semiconductor layer 6 in the channel length direction L. The conductive region, included in the oxide semiconductor, is lower in resistance than the channel region 6a.

The gate insulating film 7 is provided on the oxide semiconductor layer 6, and overlaps the channel region 6a of the oxide semiconductor layer 6. The gate electrode 8 is provided on and across the insulating film 7 from the channel region 6a.

The first interlayer insulating film 9 and the second interlayer insulating film 12 are formed to cover the oxide semiconductor layer 6 and the gate electrode 8. In the transistor 1, the source electrode 10 (on the left in FIG. 1) and the drain electrode 11 (on the right in FIG. 1) are provided on the second interlayer insulating film 12. The source electrode 10 and the drain electrode 11 are spaced apart from each other in the channel length direction L.

The source electrode 10 is electrically connected to the source region 6b of the oxide semiconductor layer 6, through a source contact hole 9a provided to the first interlayer insulating film 9 and the second interlayer insulating film 12. The drain electrode 11 is electrically connected to the drain region 6c of the oxide semiconductor layer 6, through a drain contact hole 9b provided to the first interlayer insulating film 9 and the second interlayer insulating film 12.

As can be seen, the transistor 1 includes the substrate 2 and four metal wires. On the substrate 2, the four metal wires are stacked in the order of a first metal wire, a second metal fire, a third metal wire, and a fourth metal wire. Between the metal wires, an insulating film is sandwiched. Here, the first metal wire includes: the lower electrode 4; and the constant-potential voltage line PL (see FIG. 5 to be illustrated later). The second metal wire includes: the gate electrode 8; and a second routed wire 104b (see FIG. 5 to be illustrated later). The third metal wire includes a first routed wire 104a (see FIG. 5 to be illustrated later). The fourth metal wire includes: a high power-source voltage line ELVDD of a filter circuit 105; a low power-source voltage line ELVSS of the filter circuit 105; and a connection wire connecting various wires together.

Note that the constant-potential voltage line, the first routed wire, the second routed wire, the high power-source voltage line of the filter circuit, the low power-source voltage line of the filter circuit, and the connection wire shall not be limited to the above combination. These wires may be included in any one of the four metal wires. Moreover, these wires are included in, but not limited to, the four metal wires. These wires may be included in three metal wires such as, for example, the first metal wire, the second metal wire, and the third metal wire.

The lower electrode 4 extends to intersect with the oxide semiconductor layer 6 in plan view (see FIG. 2). Moreover, the lower electrode 4 is disposed toward the source region 6b with respect to the oxide semiconductor layer 6 in the channel length direction L. Specifically, the lower electrode 4 has: a source-side end face 4a positioned toward the source region 6b, disposed in parallel with an end face of the channel region 6a (e.g, a first end face BL1), and overlap with the source region 6b; and a drain-side end face 4b positioned toward the drain region 6c, disposed in parallel with an other end face of the channel region 6a (e.g, a second end face BL2), and overlap with the channel region. The drain-side end face 4b and the end face of the channel region 6a are spaced apart from each other at an off-set distance AA in the channel length direction L. In this embodiment, the channel region 6a has a length (a channel length) of 6 μm in the channel length direction L. The off-set distance AA is preferably half as long as the channel length.

As can be seen, the lower electrode 4 is disposed toward the source region 6b, so that a breakdown voltage can be maintained high while an initial ON current is maintained high. Moreover, when the off-set distance AA is adjusted, the characteristics of the transistor 1 can be changed. Here, with the off-set distance AA set most suitably; the transistor 1 can improve in both initial characteristic and reliability.

Described next in detail is how to produce the transistor 1.

In producing the transistor 1, the underlayer 3 serving as an insulating film is deposited on the substrate 2. Examples of the substrate 2 may include a glass substrate, a silicon substrate, and a heat-resistant plastic substrate (a resin substrate). Example materials of the plastic substrate (the resin substrate) include polyethylene terephthalate (PET), polyethylene naphthalate (PEN), polyethersulfone (PES), acrylic resin, and polyimide.

In this embodiment, the underlayer 3 is a SiO₂ film deposited by chemical vapor deposition (CVD). The underlayer 3 is not limited to the SiO₂ film. For example, the underlayer 3 may be formed of such materials as silicon oxide (SiOₓ), silicon nitride (SiNₓ), silicon oxide nitride (SiOₓN_{y}; x>y), silicon oxide nitride (SiNₓO_{y}; x>y), aluminum oxide, and tantalum oxide. The underlayer 3 may be a multilayer including a plurality of layers stacked on top of an other.

Next, the lower electrode 4 is deposited on the underlayer 3 by sputtering. The lower electrode 4 may be a metal film containing an element selected from among, for example, aluminum (Al), tungsten (W), molybdenum (Mo), tantalum (Ta), chromium (Cr), titanium (Ti), and copper (Cu), or an alloy film containing these elements as ingredients. The lower electrode 4 may further be a multilayer film containing a plurality of films formed of two or more of these elements. The lower electrode 4 is patterned by photolithography to be shaped and positioned. On the lower electrode 4, the lower insulating film 5 is deposited as the underlayer 3 is. The lower insulating film 5 may be formed of the same material as the underlayer 3 is, and may be formed in a multilayer structure in which a plurality of layers are stacked on top of an other.

After that, deposited on the lower insulating film 5 is the oxide semiconductor layer 6. The oxide semiconductor layer 6, formed by, for example, sputtering, is an In—Ga—Zn—O-based semiconductor film having a thickness of 30 nm or more and 100 nm or less. In a semiconductor layer etching step, the oxide semiconductor layer 6 is patterned by photolithography and etching, and is shaped into an island to correspond to each transistor 1.

Furthermore, the gate insulating film 7 and the gate electrode 8 are deposited to cover the oxide semiconductor layer 6. The gate insulating film 7 is formed of silicon oxide (SiOₓ) deposited by the CVD. The gate insulating film 7 may be formed of the same material as the underlayer 3 is, and may be formed in a multilayer structure in which a plurality of layers are stacked on top of an other. The gate electrode 8 is deposited by sputtering. The gate electrode 8 may be formed of the same material as the lower electrode 4 is, and may be formed of a multilayer film containing a plurality of films.

The gate electrode 8 and the gate insulating film 7 are continuously etched with the same resist mask used in the patterning by photolithography. Hence, the gate electrode 8 and the gate insulating film 7, matching in patterned shape, are shaped in accordance with the same resist pattern.

Note that the matching here does not mean exact matching. The matching includes an allowance of approximately several micrometers caused by, for example, difference in etching rate. Hence, the gate electrode 8 and the gate insulating film 7 match in patterned shape to be self-aligned. Such a feature makes it possible to simplify the production step and to precisely position both the gate electrode 8 and the gate insulating film 7.

After the resist mask is removed, the entire face of the substrate 2 is treated with plasma above the gate electrode 8. The plasma treatment includes, for example, a treatment with hydrogen plasma and He plasma. In the plasma treatment, the gate electrode 8 and the gate insulating film 7 function as a mask. Hence, only a portion of the oxide semiconductor layer 6, which is not covered with either the gate electrode 8 or the gate insulating film 7 (a portion exposed from the gate insulating film 7), is reduced in resistance. That is, the channel region 6a directly below the gate electrode 8 and the gate insulating film 7 is not reduced in resistance, but the source region 6b and the drain region 6c are.

After that, the first interlayer insulating film 9 is deposited to cover the oxide semiconductor layer 6 and the gate electrode 8. On the first interlayer insulating film 9, the second interlayer insulating film 12 is deposited. The first interlayer insulating film 9 and the second interlayer insulating film 12 are formed of the same material, and by the same method, as the underlayer 3 is.

In the first interlayer insulating film 9 and the second interlayer insulating film 12, the source contact hole 9a and the drain contact hole 9b are formed in a known photolithography process to partially expose the oxide semiconductor layer 6.

After the second interlayer insulating film 12 is formed, an electrode conductive film to be a base of the source electrode 10 and the drain electrode 11 is deposited on the interlayer insulating film 12 and inside the contact holes. The electrode conductive film may be made of a material of, for example, the gate electrode 8. The electrode conductive film is patterned to form the source electrode 10 and the drain electrode 11 spaced apart from each other.

The oxide semiconductor layer 6 may be formed of not only the above material but also an other material. The oxide semiconductor contained in the oxide semiconductor layer 6 may be, for example, an amorphous oxide semiconductor (a non-crystalline oxide semiconductor) and a crystalline oxide semiconductor having a crystalline portion. Examples of the crystalline oxide semiconductor include a polycrystalline oxide semiconductor, a microcrystalline oxide semiconductor, and a crystalline oxide semiconductor whose c-axes are oriented substantially perpendicularly to the planes of the layers.

Moreover, the oxide semiconductor layer 6 may be of a multilayer structure including two or more layers. In this case, the oxide semiconductor layer 6 may include a non-crystalline oxide semiconductor layer and a crystalline oxide semiconductor layer. Alternatively, the oxide semiconductor layer 6 may include a plurality of crystalline oxide semiconductor layers having different crystal structures and a plurality of non-crystalline oxide semiconductor layers.

Described next in detail are materials and structures of the non-crystalline oxide semiconductor and the crystalline oxide semiconductor. The oxide semiconductor layer 6 may contain at least one metal element from among, for example, In, Ga, and Zn. In this embodiment, the oxide semiconductor layer 6 contains an In—Ga—Zn—O-based semiconductor (e.g. indium gallium zinc oxide). Here, the In—Ga—Zn—O-based semiconductor is a ternary oxide of In (indium), Ga (gallium), and Zn (zinc). Proportions of In, Ga, and Zn may be any given ones. For example, the proportions may include In:Ga:Zn=2:2:1, In:Ga:Zn=1:1:1, and In:Ga:Zn=1:1:2. Moreover, the In—Ga—Zn—O-based semiconductor may be amorphous or crystalline. Preferably, the In—Ga—Zn—O-based semiconductor has the c-axes oriented substantially perpendicularly to the planes of the layers.

Compared with an amorphous silicon (a-Si) TFT, a TFT including an In—Ga—Zn—O-based semiconductor layer is higher in electron mobility and lower in leak current, and preferably useful as the transistor 1 of the display device 100.

Instead of the In—Ga—Zn—O-based semiconductor, the oxide semiconductor layer 6 may contain an other oxide semiconductor such as, for example, an In—Sn—Zn—O-based semiconductor. The In—Sn—Zn—O-based semiconductor is a ternary oxide of In, Sn (tin), and Zn. An example of the In—Sn—Zn—O-based semiconductor includes In₂O₃—SnO₂—ZnO (InSnZnO).

The oxide semiconductor layer 6 shall not be limited to the above ones. Alternatively, the oxide semiconductor layer 6 may contain such substances as: an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, InGaO₃(ZnO)₅, magnesium zinc oxide (Mg_{X}Zn_{1-X}O), and cadmium zinc oxide (Cd_{X}Zn_{1-X}O). The Zn—O-based semiconductor may be non-crystalline (amorphous) ZnO, polycrystalline ZnO, or microcrystalline ZnO including non-crystalline and polycrystalline ZnO mixed together, all of which additionally contain one kind, or two or more kinds, of impurity elements from among group 1 elements, group 13 elements, group 14 elements, group 15 elements, and group 17 elements. The Zn—O-based semiconductor may also be free of impurity elements.

The transistor 1 is of a double-gate structure including the gate electrode 8 above, the lower electrode 4 below, and the oxide semiconductor layer 6 between the gate electrode 8 and the lower electrode 4. The gate electrode 8 and the lower electrode 4 may each receive a different voltage (a signal). That is, the transistor 1 may be driven by control with the voltage to be applied to the gate electrode 8. A constant potential may also be applied to the lower electrode 4 to assist the driving of the transistor 1.

Moreover, the configuration of the lower electrode 4 shall not be limited to the above one. Alternatively the lower electrode 4 may be connected to the source region 6b through, for example, a contact hole.

### Second Embodiment

Described next is the display device 100 according to a second embodiment of the present invention, with reference to the drawings. Note that identical reference signs are used to denote substantially identical constituent features between the first and second embodiments. Such constituent features will not be elaborated upon.

FIG. 3 is a block diagram schematically illustrating a display device according to the second embodiment of the present invention.

The display device 100 according to the second embodiment of the present invention includes: a display region 101 provided with pixel circuits in a matrix; and a frame region 102 provided around the display region 101. The frame region 102 includes: a terminal 103 for electrically connecting outside; a routed wire 104 extending from the terminal 103; and a filter circuit 105 (an example of a peripheral circuit) provided between the terminal unit 103 and the display region 101. The routed wire 104 includes a plurality of routed wires 104. The number of the routed wires 104 may be appropriately determined, depending on the size of the display device 100.

Possibly receiving a high voltage (noise), the filter circuit 105 is preferably a transistor with high breakdown voltage. Moreover, in case of filtering low-voltage noise, the filter circuit 105 blocks noise whose voltage is lower than a low voltage (a low power-source voltage).

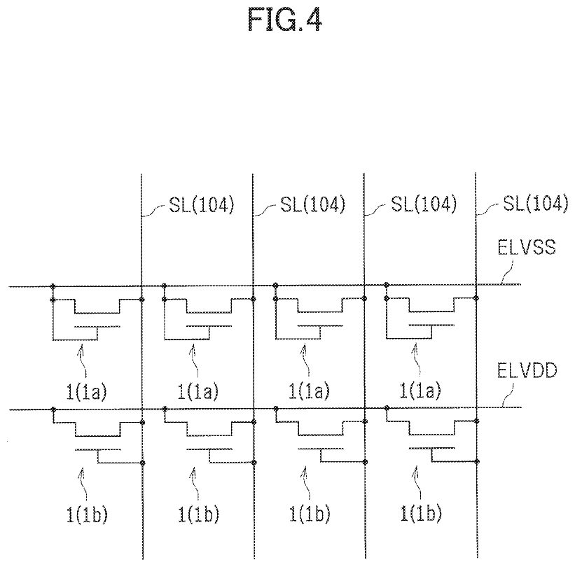

FIG. 4 is a circuit diagram illustrating a portion of a filter circuit using a transistor.

The filter circuit 105 includes a low power-source voltage line ELVSS and a high power-source voltage tine ELVDD provided to intersect with a plurality of signal wires SL (the routed wires 104). FIG. 4 shows that each of the low power-source voltage line ELVSS and the high power-source voltage line ELVDD intersects with, but not limited to, four signal wires SL. The number of the signal wires SL may be more or less than four.

The filter circuit 105 includes: a low-voltage transistor 1a (a transistor 1) connected to the low power-source voltage line ELVSS and each of the signal wires SL; and a high-voltage transistor 1b (a transistor 1) connected to the high power-source voltage line ELVDD and each of the signal wires SL. That is, the signal wires SL are not directly connected to either the low power-source voltage line ELVSS or the high power-source voltage line ELVDD. The signal wires SL are connected to the low power-source voltage line ELVSS through respective low-voltage transistors 1a, and to the high power-source voltage line ELVDD through respective high-voltage transistors 1b.

Each of the low-voltage transistors 1a has the gate electrode 8 and the drain electrode 11 connected to the low power-source voltage line ELVSS, and the source electrode 10 connected to the signal wire SL. Each of the high-voltage transistors 1b has the source electrode 10 connected to the high power-source voltage ELVDD, and the gate electrode 8 and the drain electrode 11 connected to the signal wire SL.

In the display device 100, a potential “ELVSS” and a potential “ELVDD” applied to the low power-source voltage line ELVSS and the high power-source voltage line ELVDD are each set to a predetermined value. The low-voltage transistor 1a serves as a tow-voltage filter to hold a potential applied to the signal wire SL to “ELVSS” if the applied potential is “ELVSS” or lower. The high-voltage transistor 1b serves as a high-voltage filter to hold a potential applied to the signal wire SL to “ELVDD” if the applied potential is “ELVDD” or higher.

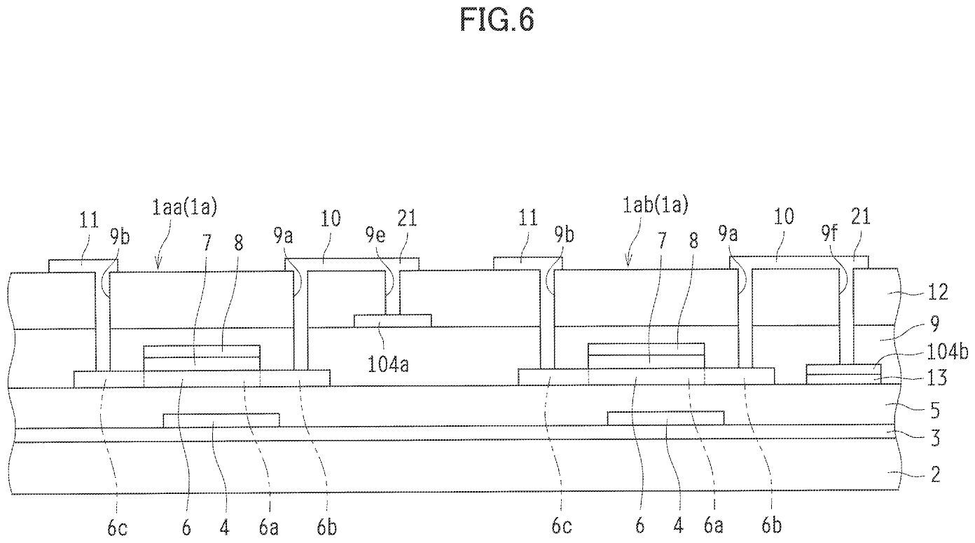

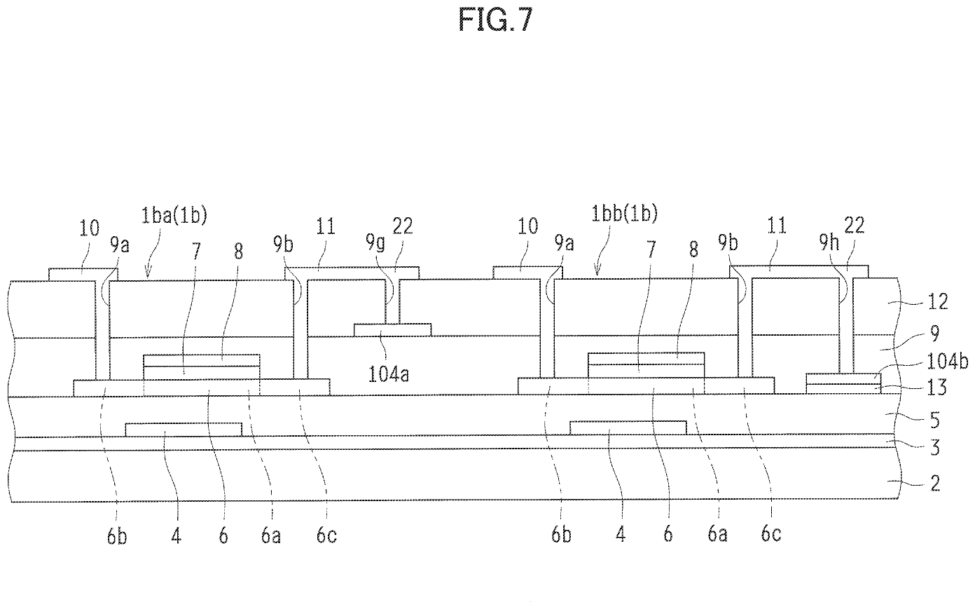

FIG. 5 is a plan view schematically illustrating some transistors of a filter circuit. FIG. 6 is a cross-sectional view schematically viewed along arrows C-C in FIG. 5. FIG. 7 is a cross-sectional view schematically viewed along arrows D-D in FIG. 5. Note that FIGS. 6 and 7 are not hatched so that the drawings are easily viewable. In FIG. 5, the lower insulating film 5 and the interlayer insulating film are transparent.

FIG. 5 selectively shows some (four) of a plurality of the transistors 1 provided to the filter circuit 105, and illustrates two of the low-voltage transistors 1a and two of the high-voltage transistor 1b. FIG. 6 illustrates a filter circuit filtering low-voltage noise and including the two low-voltage transistors 1a. FIG. 7 illustrates a filter circuit filtering high-voltage noise and including the two high-voltage transistors 1b. In this embodiment, the routed wires 104 are of two kinds each provided in a different layer. Specifically, the two kinds of routed wires 104 include: a first routed wire 104a provided on the first interlayer insulating film 9; and a second routed wire 104b provided above the lower insulating film 5 through a wire insulating film 13. One of the two low-voltage transistors 1a; namely, a first low-voltage transistor 1aa, is connected to the first routed wire 104a. An other one of the two low-voltage transistors 1a; namely, a second low-voltage transistor 1ab, is connected to the second routed wire 104b. One of the two high-voltage transistors 1b; namely, a first high-voltage transistor 1ba, is connected to the first routed wire 104a. An other one of the two high-voltage transistors 1b; namely, a second high-voltage transistor 1bb, is connected to the second routed wire 104b.

After the first interlayer insulating film 9 is formed and before the second interlayer insulating film 12 is deposited, a metal film may be deposited and patterned to form the first routed wire 104a. Moreover, a contact hole for the first routed wire 104a is etched into the second interlayer insulating film 12 together with, or separately from, the source contact hole 9a and the drain contact hole 9b.

The second routed wire 104b is formed together with the gate insulating film 7 and the gate electrode 8. That is, in the photolithography of the gate electrode 8, the resist mask may also be formed on a portion corresponding to the second routed wire 104b. Hence, in etching the gate insulating film 7 and the gate electrode 8, the second routed wire 104b and the wire insulating film 13 matching the second routed wire 104b are simultaneously formed. Furthermore, a contact hole for the second routed wire 104b may be etched into the first interlayer insulating film 9 and the second interlayer insulating film 12 together with, or separately from, the source contact hole 9a and the drain contact hole 9b.

The low power-source voltage line ELVSS and the high power-source voltage line ELVDD are formed together with the source electrode 10 and the drain electrode 11, and provided above the first interlayer insulating film 9. That is, the low power-source voltage line ELVSS and the high power-source voltage line ELVDD are formed of an electrode conductive film forming the source electrode 10 and the drain electrode 11. The electrode conductive film is patterned and shaped to also include the low power-source voltage line ELVSS and the high power-source voltage line ELVDD.

Each low-voltage transistor 1a includes a source extension 21 extending from the source electrode 10 to the first routed wire 104a and the second routed wire 104b, and electrically connecting to the first routed wire 104a and the second routed wire 104b. Moreover, a drain extension 22 extends from the drain electrode 11 to the low power-source voltage lure ELVSS, and electrically connects to the low power-source voltage line ELVSS. Furthermore, a gate extension 23 extends from the low power-source voltage line ELVSS to the gate electrode 8, and electrically connects to the gate electrode 8.

Each high-voltage transistor 1b includes the source extension 21 extending from the source electrode 10 to the high power-source voltage line ELVDD, and electrically connecting to the high power-source voltage line ELVDD. Moreover, the drain extension 22 extends from the drain electrode 11 to the first routed wire 104a and the second routed wire 104b, and electrically connects to the first routed wire 104a and the second routed wire 104b. Furthermore, the gate extension 23 extends from the first routed wire 104a and the second routed wire 104b to the gate electrode 8, and electrically connects to the first routed wire 104a and the second routed wire 104b.

The source extension 21, the drain extension 22, and the gate extension 23 are formed of the above electrode conductive film, together with the source electrode 10 and the drain electrode 11. If the source extension 21, the drain extension 22, and the gate extension 23 connect to wires in different layers, contact holes may be formed appropriately in a portion where the extensions and the wires overlap.

In the first low-voltage transistor 1aa, the source extension 21 is connected through a routing contact hole 9e to the first routed wire 104a. In the second low-voltage transistor 1ab, the source extension 21 is connected through a routing contact hole 9f to the second routed wire 104b. Moreover, each gate extension 23 of the first low-voltage transistor 1aa and the second low-voltage transistor 1ab is connected to the corresponding gate electrode 8 through a contact hole 9c formed through the first interlayer insulating film 9 and the second interlayer insulating film 12 above the gate electrode 8.

In the first high-voltage transistor 1ba, the drain extension 22 is connected through a routing contact hole 9g to the first routed wire 104a. In the second high-voltage transistor 1bb, the drain extension 22 is connected through a routing contact hole 9h to the second routed wire 104b. Furthermore, each gate extension 23 in the first high-voltage transistor 1ba and the second high-voltage transistor 1bb is connected through a routing contact hole 9d to the second routed wire 104b. Note that the gate extension 23 and the gate electrode 8 may be connected together through the contact hole 9c as provided in the first low-voltage transistor 1aa and the second low-voltage transistor 1ab.

Note that the source electrode 10 and the drain electrode 11 may overlap the oxide semiconductor layer 6 in any given range. The source electrode 10 and the drain electrode 11 may be provided so that various wires are lead to the corresponding contact holes.

In each of the two low-voltage transistors 1a, the lower electrode 4 is connected to a constant potential voltage line PL. Moreover, in each of the two high-voltage transistors 1b, the lower electrode 4 is connected to the constant potential voltage line PL. The constant potential voltage line PL includes two constant potential voltage lines PL each corresponding to one of the low-voltage transistor 1a and the high-voltage transistor 1b. The two constant potential voltage lines PL may have their ends connected together.

As illustrated in FIG. 6, a circuit to filter low-voltage noise includes the low-voltage transistor 1a having the lower electrode 4 offset toward the source region 6b connected to the routed wire 104. Moreover, as illustrated in FIG. 7, a circuit to filter high-voltage noise includes the high-voltage transistor 1b having the lower electrode 4 offset toward the source region 6b connected to the high power-source voltage line ELVDD.

FIG. 5 selectively illustrates, but not limited to, four of the transistors 1 in the filter circuit 105. The number of the transistors may be increased or decreased, depending on the number of the routed wires 104. As to the routed wires 104, the first routed wire 104a and the second routed wire 104b may be alternately arranged. Alternatively, either the first routed wire 104a or the second routed wire 104b may be continuously disposed.

In the transistor 1 according to this embodiment, various wires such as the gate electrode 8, the source electrode 10, the drain electrode 11, and the routed wires 104 are stacked on top of an other with various insulating films sandwiched therebetween, and connected through the contact holes. Such a configuration is an example, and the order of the stacking various wires may be rearranged appropriately. In the above configuration, for example, such various wires as the source electrode 10, the source extension 21, the low power-source voltage line ELVSS, and the high power-source voltage line ELVDD are provided in the same layer and thrilled of the same electrode conductive film at a time. Alternatively, the various wires may be deposited separately in different layers.

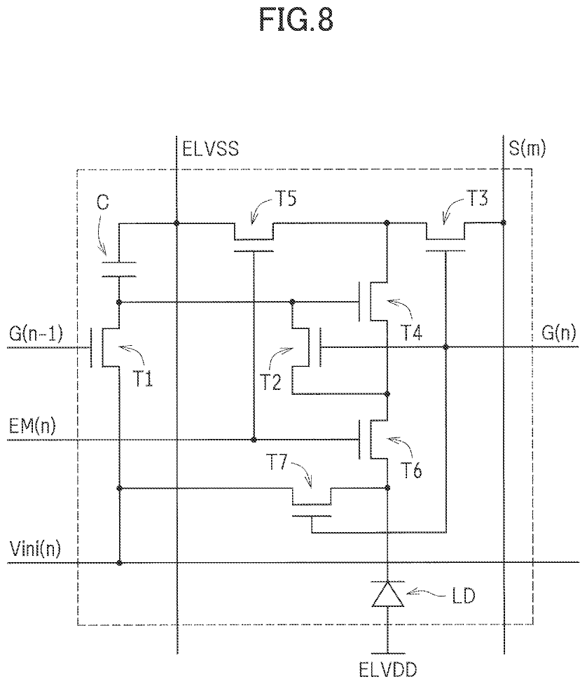

FIG. 8 is an equivalent circuit diagram illustrating a pixel circuit of the display device.

The display device 100 includes the display region 101 in which a plurality of pixels are arranged in a matrix. The pixels typically include red pixels glowing red, green pixels glowing green, and blue pixels glowing blue. Each of the pixels is provided with a corresponding light-emitting diode LD, and controlled by a corresponding pixel circuit.

A straight line corresponding to “S(m)” indicates a source signal line. Straight lines corresponding to “G(n)” and “G(n−1)” indicate gate signal lines. A straight line corresponding to “EM(n)” indicates a light-emission control line. Moreover, “ELVDD” indicates a high power-source voltage, and a straight line led to “ELVDD” corresponds to a high power-source voltage line. Furthermore, “ELVSS” indicates a low power-source voltage, and a straight line led to “ELVSS” corresponds to a low power-source voltage line. A straight line corresponding to “Vini(n)” indicates a reset signal line corresponding to a reset potential.

FIG. 8 illustrates an example of the pixel circuit including a combination of: seven transistors (a first circuit transistor T1 to a seventh circuit transistor T7); a capacitor C1; and a light-emitting diode LD. The above transistor 1 is applicable as any one of the first circuit transistor T1 to the seventh circuit transistor T7. The transistor 1 is desirably positioned in accordance with the characteristics of the first circuit transistor T1 to the seventh circuit transistor T7, and preferably applicable as a switching transistor in the pixel circuit.

In the pixel circuit, the first circuit transistor T1 to the third circuit transistor T3 and the fifth circuit transistor T5 to the seventh circuit transistor T7 are used as switching transistors. Moreover, the fourth circuit transistor T4 serves as a drive transistor to supply power to the light-emitting diode LD.

The display device 100 according to this embodiment may be any given display panel as long as the display panel includes display elements. Of the display elements, brightness and transmittance are controlled either by current or by voltage. Examples of the display elements to be controlled by current include those of: an electroluminescence (EL) display such as an organic EL display including an organic light-emitting diode (OLED) and an inorganic EL display including an inorganic light-emitting diode; and a quantum-dot light-emitting diode (QLED) display including a QLED. Moreover, examples of the display elements to be controlled by voltage include liquid crystal elements.

The embodiments disclosed herewith are examples in all respects, and shall not be cited as grounds for limitative interpretation. Hence, the technical scope of the present invention shall not be interpreted not by the above embodiments alone but by recitations of claims. All the modifications equivalent to the features of, and within the scope of, the claims are to be included within the scope of the present invention.

### REFERENCE SIGNS LIST

1 Transistor

2 Substrate

3 Underlayer

4 Lower Electrode

4a Source-Side End Face

4b Drain-Side End Face

5 Lower Insulating Film

6 Oxide Semiconductor Layer

6a Channel Region

6b Source Region

6c Drain Region

7 Gate Insulating Film

8 Gate Electrode

9 First Interlayer Insulating Film

10 Source Electrode

11 Drain Electrode

12 Second Interlayer Insulating Film

100 Display Device

101 Display Region

102 Frame Region

103 Terminal

104 Routed Wire

105 Filter Circuit

AA Off-Set Distance

ELVDD High Power-Source Voltage Line

ELVSS Low Power-Source Voltage Line

L Channel Length Direction

1. A display device, comprising
a transistor including: a substrate; a lower electrode; a lower insulating film; an oxide semiconductor layer; a gate insulating film; and a gate electrode stacked on top of an other in a stated order,
the gate electrode matching the gate insulating film in plan view,
the oxide semiconductor layer including: a channel region across the gate insulating film from the gate electrode; and a source region and a drain region provided to sandwich the channel region, and
the lower electrode:
extending to intersect with the oxide semiconductor layer in plan view,
having a source-side end face positioned toward the source region, disposed in parallel with an end face of the channel region, and overlap with the source region, and
having a drain-side end face positioned toward the drain region, disposed in parallel with an other end face of the channel region, and overlap with the channel region.

2. The display device according to claim 1, wherein
when a direction in which the source region and the drain region face each other is defined as a channel length direction,
the drain-side end face and an end face of the channel region are spaced apart from each other at an off-set distance in the channel length direction.

3. The display device according to claim 2, wherein
the off-set distance is shorter than, or equal to, half as long as the channel region in the channel length direction.

4. The display device according to claim 1, further comprising
a plurality of pixel circuits arranged in a matrix and provided to a display region, wherein
the transistor is a switching transistor included in each of the pixel circuits.

5. The display device according to claim 1, further comprising
a peripheral circuit monolithically provided to a frame region, wherein
the transistor is a switching transistor included in the peripheral circuit.

6. The display device according to claim 1, further comprising:
a terminal provided to a frame region;
a routed wire extending from the terminal; and
a filter circuit provided between the terminal and a display region, wherein
the terminal is electrically connected to a wire of the display region through the filter circuit, and
the transistor is included in the filter circuit.

7. The display device according to claim 6, wherein
the source region is electrically connected to a high power-source voltage line, and
the drain region and the gate electrode are electrically connected to the routed wire.

8. The display device according to claim 6, wherein
the source region is electrically connected to the routed wire, and
the drain region and the gate electrode are electrically connected to a low power-source voltage line.

9. The display device according to claim 7, wherein
the routed wire is electrically connected to a data signal line of the display region.

10. The display device according to claim 7, wherein
the routed wire is electrically connected to a scanning signal line of the display region.

11. The display device according to claim 1, wherein
the lower electrode is electrically connected to the source region.

12. The display device according to claim 1, wherein
the lower electrode is electrically connected to a constant-potential voltage line.
